(19) United States
(12) Patent Application Publication
(10) Pub. No.: US 2015/0322562 A1
(43) Pub. Date: Nov. 12, 2015

(54) MASK PLATE AND METHOD FOR MANUFACTURING THE SAME

(71) Applicants: BOE TECHNOLOGY GROUP CO., LTD., BEIJING (CN); HEFEI XINSHENG OPTOELECTRONICS TECHNOLOGY CO., LTD, ANHUI (CN)

(72) Inventor: SHENGKAI PAN, BEIJING (CN)

(73) Assignees: BOE TECHNOLOGY GROUP CO., LTD., BEIJING (CN); HEFEI XINSHENG OPTOELECTRONICS TECHNOLOGY CO., LTD, ANHUI (CN)

(21) Appl. No.: 14/498,768

(22) Filed: Sep. 26, 2014

(30) Foreign Application Priority Data
May 9, 2014 (CN) 201410195772.5

(51) Int. Cl. C23C 14/04

(52) U.S. Cl. CPC C23C 14/042

(57) ABSTRACT

The present disclosure provides a mask plate and a method for manufacturing the same. The mask plate includes a metal substrate having at least one first hollowed region and an organic covering layer having at least one second hollowed region. A projection of the second hollowed region is located within the first hollowed region. The organic covering layer partially or completely covers the metal substrate.

### CROSS-REFERENCE TO RELATED APPLICATION

This application claims priority to Chinese Patent Application No. 201410195772.5 filed on May 9, 2014, the disclosure of which is incorporated in its entirety by reference herein.

### TECHNICAL FIELD

The present disclosure relates to the field of display technology, and more particularly to a mask plate and a method for manufacturing the same.

### BACKGROUND

Comparing with a typical liquid crystal display (LCD) mode, an organic electroluminescence display (OLED) technology does not require a backlight, and has characteristics of self-luminous. An OLED includes an organic material film and a glass substrate which are very thin. When a current is passed, the organic material emits light. Thus, the OLED screen may significantly save energy, be made thinner and lighter, tolerate a wider range of temperature than the LCD screen and have a larger viewing angle. An emitting layer of the OLED screen is usually formed by using the evaporation deposition film technology to make organic material pass through a high-precision metal mask plate to form organic light-emitting components on corresponding pixel positions of an array substrate.

With development of the OLED technology, especially the presence of the active matrix/organic light emitting diode (AMOLED), sizes of OLED products and sizes of glass substrates are increasing. This also requires increasing sizes of high-precision metal mask plates. The existing high-precision metal mask plates are usually manufactured through photolithography process, which requires a coating machine, a high-precision exposure machine, a chemical etching machine, etc., and the best opening precision may reach ±3 um. With larger AMOLED production lines being put into use, related machines for manufacturing the high-precision metal mask plates are seriously lagged, and it is needed to research and manufacture the related machines. However, the research and manufacture is expensive, and requires a large investment. Further, when using the photolithography process to manufacture a high-precision metal mask plate, it is needed to manufacture a light mask first; if a layout of the high-precision metal mask plate is changed, the light mask cannot be used again. In summary, using the photolithography process to manufacture high-precision metal mask plates has a long manufacturing cycle and a high production cost.

In order to reduce production cost and shorten the manufacturing cycle, a laser cutting machine may be adopted to manufacture a high-precision metal mask plate. The laser cutting machine itself has a high machining precision, for example, the best machining precision may reach ±2-3 um. A high-precision metal mask plate may be formed by using a laser to thermally cut a thin metal sheet. However, heat will be generated when the laser thermally cuts the thin metal sheet, thus, thermal deformation easily occurs on the thin metal sheet, resulting in accumulation of stress in the thin metal sheet which cannot be released. When the thin metal sheet is stretched on a frame of a mask plate, the thin metal sheet is easily wrapped and folded by a tension force generated by the frame, which adversely affects flatness and straightness of the high-precision metal mask plate, thus, an actual opening precision of the high-precision metal mask plate manufactured by adopting the laser cutting machine is usually larger than 50 um or worse.

### SUMMARY

One technical problem to be solved by one embodiment of the present disclosure is to provide a mask plate and a method for manufacturing the same, which may use a laser cutting machine to produce mask plates of high precision and having a good opening precision.

In order to solve the above technical problem, embodiments of the present disclosure provides following technical solution.

On one hand, a mask plate is provided and includes:

a metal substrate having at least one first hollowed region; and

an organic covering layer having at least one second hollowed region; wherein a projection of the second hollowed region is located within the first hollowed region; the organic covering layer partially or completely covers the metal substrate.

Further, the metal substrate is made of invar steel or stainless steel.

Further, the organic covering layer is made of photoresist or flattening glue which is able to withstand high temperatures above 300 degrees.

Further, a thickness of the organic covering layer is 10-200 um.

Further, flatness of the organic covering layer is not more than 50 um.

One embodiment of the present disclosure further provides a method for manufacturing a mask plate including:

placing a metal substrate to be manufactured on a cutting machine, and stretching the metal substrate;

forming at least one first hollowed region by performing a first cutting operation on the metal substrate;

forming an organic covering layer on the metal substrate in which the first hollowed region is formed; the organic covering layer partially or completely covering the metal substrate;

forming at least one second hollowed region by performing a second cutting operation on the organic covering layer in such a manner that a projection of the second hollowed region is located within the first hollowed region.

Further, after the stretching the metal substrate, flatness of the metal substrate is not more than 50 um.

Further, before the forming an organic covering layer on the metal substrate in which the first hollowed region is formed, the method further includes:

removing impurity particles attached to the metal substrate.

Further, the forming an organic covering layer on the metal substrate in which the first hollowed region is formed includes:

coating a layer of organic plastic material on the metal substrate in which the first hollowed region is formed, and curing the organic plastic material to form the organic covering layer.

Further, before the performing a second cutting operation on the organic covering layer, the method further includes:

stretching the metal substrate on which the organic covering layer is formed.

One embodiment of the present disclosure further provides a method for manufacturing a mask plate including:

forming at least one first hollowed region by performing a first cutting operation on a substrate to be manufactured;

covering the first hollowed region with an organic covering layer;

forming at least one second hollowed region by performing a second cutting operation on the organic covering layer in such a manner that a projection of the second hollowed region is located within the first hollowed region.

Further, the substrate is made of metal.

Further, the organic covering layer is made of photoresist or flattening glue which is able to withstand high temperatures above 300 degrees.

Further, the covering the first hollowed region with an organic covering layer includes:

coating a layer of organic plastic material on the substrate in which the first hollowed region is formed, and curing the organic plastic material to form the organic covering layer partially or completely covering the metal substrate.

Embodiments of the present disclosure have following benefit effects.

In the above solution, first performing the first laser cutting operation on the metal substrate to form the first hollowed region, then forming the organic covering layer on the metal substrate and performing the second laser cutting operation on the organic covering layer to form the second hollowed region; later, the organic covering layer covering on the metal substrate may be used as a mask when forming a light-emitting layer via evaporation deposition. Since the second cutting operation is to use the laser to cut the organic covering layer, thus, thermal deformation does not occur on the metal substrate below the organic covering layer. Therefore, the machining precision of the organic covering layer is determined by the cutting machine itself, for example, the best machining precision may reach ±2-3 um. With the improvement of the machining precision, tension force required for stretching the metal substrate may be reduced, and the possibility that the metal substrate is wrapped and folded under action of a force may also be reduced, thus, the opening precision of the mask plate may be effectively improved. Comparing with using a lithography process to manufacture a high precision metal mask plate, the technical solution of the present disclosure may shorten the manufacturing cycle, reduce production cost, and require only a simple modification of the existing equipment and have high feasibility.

### BRIEF DESCRIPTION OF THE DRAWINGS

FIG. 1 is a flow chart of a method for manufacturing a mask plate according to one embodiment of the present disclosure;

FIG. 2 is a top view of a mask plate according to one embodiment of the present disclosure;

FIG. 3 is a schematic sectional view of the mask plate of FIG. 2 taken along an AA′ direction.

### DETAILED DESCRIPTION

In order to make the above objects, features and advantages of the embodiments of the present disclosure more clear, the technical solutions according to the embodiments of the present disclosure will be clearly and fully described hereinafter in conjunction with the accompanying drawings in the embodiments of the present disclosure.

For the problem in the prior art that the opening precision of the high-precision metal mask plate manufactured by adopting the laser cutting machine is worse, one embodiment of the present disclosure provides a mask plate and a method for manufacturing the same, which may use a laser cutting machine to produce mask plates of high precision and having a good opening precision.

One embodiment of the present disclosure provides a mask plate including:

a metal substrate having at least one first hollowed region; and

an organic covering layer having at least one second hollowed region; a projection of the second hollowed region being located within the first hollowed region.

The organic covering layer partially or completely covers the metal substrate.

In the mask plate of one embodiment of the present disclosure, in fact, the second hollowed region in the organic covering layer on the metal substrate is taken as a mask pattern. Since thermal deformation does not occur in the organic covering layer when cutting the organic covering layer, thus, machining precision of the organic covering layer is determined by a cutting machine itself, for example, the best machining precision may reach ±2-3 um. With the improvement of the machining precision, tension force required for stretching the metal substrate may be reduced, and the possibility that the metal substrate is wrapped and folded under action of a force may also be reduce, thus, the opening precision of the mask plate may be effectively improved.

Optionally, the metal substrate may be made of invar steel or stainless steel.

Further, the organic covering layer may be made of organic plastic material. The organic plastic material may be made of photoresist or flattening glue which is able to withstand high temperatures above 300 degrees. Optionally, a thickness of the organic covering layer is 10-200 um.

Further, in order to ensure the opening precision of the mask plate, flatness of the organic covering layer is not more than 50 um. The flatness of the organic covering layer refers to a vertical distance between a highest point and a lowest point in a cross section of the organic covering layer.

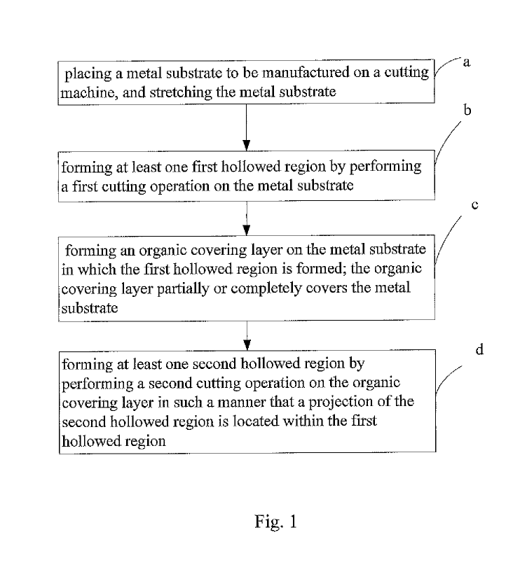

FIG. 1 is a flow chart of a method for manufacturing a mask plate according to one embodiment of the present disclosure. As shown in FIG. 1, the method of this embodiment includes:

Step a: placing a metal substrate to be manufactured on a cutting machine, and stretching the metal substrate;

Step b: forming at least one first hollowed region by performing a first cutting operation on the metal substrate;

Step c: forming an organic covering layer on the metal substrate in which the first hollowed region is formed; the organic covering layer partially or completely covers the metal substrate;

Step d: forming at least one second hollowed region by performing a second cutting operation on the organic covering layer in such a manner that a projection of the second hollowed region is located within the first hollowed region.

The cutting process in this embodiment may adopt laser cutting, or other cutting methods. Following description will take the laser cutting as an example for illustration.

When manufacturing the mask plate in this embodiment, first performing the first laser cutting operation on the metal substrate to form the first hollowed region, then forming the organic covering layer on the metal substrate and performing the second laser cutting operation on the organic covering layer to form the second hollowed region; later, the organic covering layer covering on the metal substrate may be used as a mask when forming a light-emitting layer via evaporation deposition. Since the second cutting operation is to use the laser to cut the organic covering layer, thus, thermal deformation does not occur on the metal substrate below the organic covering layer. Therefore, the machining precision of the organic covering layer is determined by a laser cutting machine itself, for example, the best machining precision may reach ±2-3 um. With the improvement of the machining precision, tension force required for stretching the metal substrate may be reduced, and the possibility that the metal substrate is wrapped and folded under action of a force may also be reduced, thus, the opening precision of the high-precision mask plate manufactured by adopting the laser may be effectively improved. Comparing with using a lithography process to manufacture a high precision metal mask plate, the technical solution of the present disclosure may shorten the manufacturing cycle, reduce production cost, and require only a simple modification of the existing equipment and have high feasibility.

Further, in another embodiment of the present disclosure, on the basis of the above steps a-d, after stretching the metal substrate of the step a, the flatness of the metal substrate is not more than 50 um.

Further, in another embodiment of the present disclosure, on the basis of the above steps a-d, before the step c, the method further includes:

removing impurity particles attached to the metal substrate.

Further, in another embodiment of the present disclosure, on the basis of the above steps a-d, the step c includes:

coating a layer of organic plastic material on the metal substrate in which the first hollowed region is formed, and curing the organic plastic material to form the organic covering layer. Specifically, the organic plastic material may be photoresist or flattening glue which is able to withstand high temperatures above 300 degrees. Optionally, a thickness of the organic covering layer is 10-200 um.

Further, in another embodiment of the present disclosure, on the basis of the above steps a-d, before performing a second laser cutting operation on the organic covering layer, the method further includes:

stretching the metal substrate on which the organic covering layer is formed.

The mask plate and the method for manufacturing the same of the present disclosure will be described in details with drawings and specific embodiments. A method for manufacturing a mask plate in one embodiment includes following steps.

Step 1: placing a metal substrate to be manufactured on a platform of a laser cutting machine.

The metal substrate may be made of invar steel or stainless steel. Optionally, a thickness of the metal substrate may be in a range of 50-200 um.

Step 2: stretching the metal substrate in a manner that ensures that flatness of the metal substrate is not more than 50 um or better.

The flatness of the metal substrate refers to a vertical distance between a highest point and a lowest point in a cross section of the metal substrate.

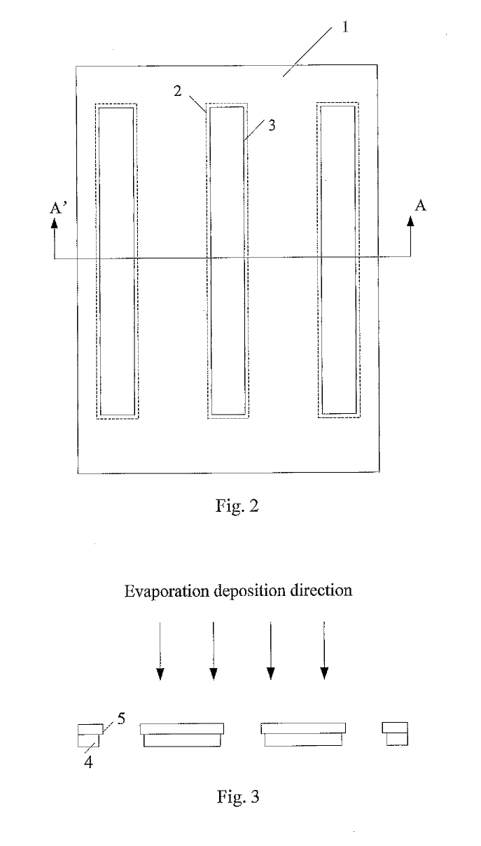

Step 3: performing a first cutting operation on the metal substrate via laser. As shown in FIG. 2, the numeral 2 represents an opening pattern obtained by the first cutting operation. After the first cutting operation, a plurality of opens is formed in the metal substrate. The plurality of opens is corresponding to opens required by the mask plate in a one-to-one manner. Each of the opens formed in the metal substrate has a size larger than that of the corresponding open required by the mask plate. Specifically, sizes and shapes of the opens formed in the metal substrate may be set according to sizes and thickness of the metal substrate and requirements. For example, an open in the mask plate is a square of 5*5 um, then, a corresponding open in the metal substrate may be a square of 8*8 um.

Step 4: removing impurity particles attached to the metal substrate. Specifically, the impurity particles attached to the metal substrate may be removed by using a cleaning device to clean the metal substrate, or using a fan to blow the impurity particles away. If there are impurity particles attached to the metal substrate, the impurity particles adversely affect the flatness of the organic covering layer when forming the organic covering layer, and thus a final machining precision is affected.

Step 5: forming an organic covering layer on the metal substrate. Specifically, a layer of organic plastic material may be coated on the metal substrate through a coating machine, and the organic plastic material is cured to form the organic covering layer. The selected organic plastic material is required to be able to withstand a temperature of the evaporation deposition process, have a certain toughness and good adhesiveness, and be difficult to peel off from the metal substrate. Specifically, the organic plastic material may be existing photoresist or flattening glue. Temperature of the evaporation deposition process is usually above 300 degrees Celsius, the existing photoresist or flattening glue may withstand a high temperature above 500 degrees Celsius, thus the existing photoresist or flattening glue may satisfy the requirements. A thickness of the organic covering layer may be set according to sizes of opens required by the mask plate and the thickness of the metal substrate. A thickness of the organic plastic material may be controlled by setting working parameters of the coating machine. Optionally, the thickness of the organic covering layer is in a range of 10-200 um. Of course, the organic covering layer may also be formed by using other deposition methods.

Step 6: placing the metal substrate on which the organic covering layer is formed on the platform of the laser cutting machine.

Step 7: stretching the metal substrate on which the organic covering layer is formed in a manner that ensures that flatness of the metal substrate is not more than 50 um or better.

Step 8: performing a second cutting operation on the organic covering layer on the metal substrate via laser. As shown in FIG. 2, the numeral 3 represents an opening pattern obtained by the second cutting operation. After the second cutting operation, a plurality of opens is formed in the organic covering layer. The plurality of opens formed in the organic covering layer is corresponding to opens required by the mask plate in a one-to-one manner. Each of the opens formed in the organic covering layer has a size substantially equal to a size of the corresponding open required by the mask plate. In theory, the size of each of the opens formed in the organic covering layer is equal to the size of the corresponding open required by the mask plate, however, affected by the machining precision, there is a slight deviation between the size of each of the opens formed in the organic covering layer and the size of the corresponding open required by the mask plate. The opening precision is determined by the laser cutting machine itself, and the deviation between the size of each of the opens formed in the organic covering layer and the size of the corresponding open required by the mask plate is substantially 2-3 um.

Since the second cutting operation is to use the laser to cut the organic covering layer, the laser does not contact the metal substrate below the organic covering layer, thus, thermal deformation does not occur on the metal substrate below the organic covering layer. Therefore, the machining precision is not affected. With the improvement of the machining precision, tension force required for stretching the metal substrate may be reduced, and the possibility that the metal substrate is wrapped and folded under action of a force may also be reduced, thus, the opening precision of the high-precision mask plate manufactured by adopting the laser may be effectively improved.

The mask plate of this embodiment may be formed through the above steps 1-8. As shown in FIGS. 2-3, the mask plate 1 is composed of two parts, which are a metal substrate 4 and an organic covering layer 5, respectively. The metal substrate 4 includes a plurality of opens. The opens of the metal substrate 4 is corresponding to opens required by the mask plate in a one-to-one manner. Each of the opens formed in the metal substrate has a size slightly larger than that of the corresponding open required by the mask plate. The organic covering layer 5 includes a plurality of opens which are corresponding to the opens required by the mask plate in a one-to-one manner. Each of the opens formed in the organic covering layer 5 has a size substantially equal to a size of the corresponding open required by the mask plate. In fact, the metal substrate 4 is used as a carrier of a mask, and the organic covering layer 5 covering on the metal substrate 4 is used as the mask when forming a light-emitting layer via evaporation deposition.

In this embodiment, first performing the first laser cutting operation on the metal substrate, then forming the organic covering layer on the metal substrate and performing the second laser cutting operation on the organic covering layer, to form the organic covering layer which includes opens required by the mask plate. Later, the organic covering layer covering on the metal substrate may be used as a mask when forming a light-emitting layer via evaporation deposition. Since the second cutting operation is to use the laser to cut the organic covering layer, thus, thermal deformation does not occur on the metal substrate below the organic covering layer. Therefore, the machining precision of the organic covering layer is determined by a laser cutting machine itself, for example, the best machining precision may reach ±2-3 um. With the improvement of the machining precision, tension force required for stretching the metal substrate may be reduced, and the possibility that the metal substrate is wrapped and folded under action of a force may also be reduce, thus, the opening precision of the high-precision mask plate manufactured by adopting the laser may be effectively improved. Comparing with using a lithography process to manufacture a high-precision metal mask plate, the technical solution of the present disclosure may shorten the manufacturing cycle, reduce production cost, and require only a simple modification of the existing equipment and have high feasibility.

In each embodiment of the method, the number of steps is not used to limit the sequence of steps. A person skilled in the art may change the sequence of steps without departing from the scope of the present disclosure, and these changes should also be considered as within the scope of the present disclosure.

The foregoing are merely exemplary embodiments of the present disclosure. It should be appreciated that, a person skilled in the art may make further modifications and improvements without departing from the scope of the present disclosure, and these modifications and improvements should also be considered as within the scope of the present disclosure.

What is claimed is:

1. A mask plate comprising:
a metal substrate having at least one first hollowed region; and
an organic covering layer having at least one second hollowed region; wherein a projection of the second hollowed region is located within the first hollowed region;
the organic covering layer partially or completely covers the metal substrate.

2. The mask plate according to claim 1, wherein the metal substrate is made of invar steel or stainless steel.

3. The mask plate according to claim 1, wherein the organic covering layer is made of photoresist or flattening glue which is able to withstand high temperatures above 300 degrees.

4. The mask plate according to claim 1, wherein a thickness of the organic covering layer is 10-200 um.

5. The mask plate according to claim 1, wherein flatness of the organic covering layer is not more than 50 um.

6. A method for manufacturing a mask plate comprising:
placing a metal substrate to be manufactured on a cutting machine, and stretching the metal substrate;
forming at least one first hollowed region by performing a first cutting operation on the metal substrate;
forming an organic covering layer on the metal substrate in which the first hollowed region is formed; the organic covering layer partially or completely covering the metal substrate;
forming at least one second hollowed region by performing a second cutting operation on the organic covering layer in such a manner that a projection of the second hollowed region is located within the first hollowed region.

7. The method according to claim 6, wherein after the stretching the metal substrate, flatness of the metal substrate is not more than 50 um.

8. The method according to claim 6, wherein before the forming an organic covering layer on the metal substrate in which the first hollowed region is formed, the method further comprises:
removing impurity particles attached to the metal substrate.

9. The method according to claim 6, wherein the forming an organic covering layer on the metal substrate in which the first hollowed region is formed comprises:
coating a layer of organic plastic material on the metal substrate in which the first hollowed region is formed, and curing the organic plastic material to form the organic covering layer.

10. The method according to claim 6, wherein before the performing a second cutting operation on the organic covering layer, the method further comprises:
stretching the metal substrate on which the organic covering layer is formed.

11. A method for manufacturing a mask plate comprising:
forming at least one first hollowed region by performing a first cutting operation on a substrate to be manufactured;
covering the first hollowed region with an organic covering layer;
forming at least one second hollowed region by performing a second cutting operation on the organic covering layer in such a manner that a projection of the second hollowed region is located within the first hollowed region.

12. The method according to claim 11, wherein the substrate is made of metal.

13. The method according to claim 12, wherein the organic covering layer is made of photoresist or flattening glue which is able to withstand high temperatures above 300 degrees.

14. The method according to claim 11, wherein the covering the first hollowed region with an organic covering layer comprises:
coating a layer of organic plastic material on the substrate in which the first hollowed region is formed, and curing the organic plastic material to form the organic covering layer partially or completely covering the metal substrate.
